(19) United States
(12) Patent Application Publication
(10) Pub. No.: US 2008/0276980 A1
(43) Pub. Date: Nov. 13, 2008

(54) SOLAR CELL MODULE

(75) Inventor: Satoru OGASAHARA, Kobe-shi (JP)

Correspondence Address: DITTHAVONG MORI & STEINER, P.C., 918 Prince St., Alexandria, VA, 22314, US

(73) Assignee: Sanyo Electric Co., Ltd., Moriguchi-shi (JP)

(21) Appl. No.: 12/033,495

(22) Filed: Feb. 19, 2008

(30) Foreign Application Priority Data
Feb. 19, 2007 (JP) JP2007-037367

(51) Int. Cl. H01L 31/042

(52) U.S. Cl. 136/244

(57) ABSTRACT

A solar cell module capable of suppressing reduction in output is obtained. This solar cell module includes a first cell and a second cell adjacent to each other, each including a first electrode layer, a power generating Layer formed oil a surface of the first electrode layer and a second electrode layer formed on a surface of the power generating layer stacked with each other, wherein a first electrode layer of the first cell and a second electrode layer of the second cell are electrically connected to each other, and a stress relief region having a thickness smaller than the thickness of overall the power generating layer is formed on a prescribed region of the power generating layer.

### BACKGROUND OF THE INVENTION

1. Field of the Invention

This invention relates to a solar cell module, and more particularly, it, relates to a solar cell module comprising a power generating layer constituted by a first photoelectric conversion layer made of an amorphous silicon layer and a second photoelectric conversion layer made of a microcrystalline silicon layer.

2. Description of the Background Art

A solar cell module comprising a power generating layer constituted by a first photoelectric conversion layer made of an amorphous silicon layer and a second photoelectric conversion layer made of a microcrystalline silicon layer is known in general as disclosed in Japanese Patent Laying-Open No. 2005-116930.

The aforementioned Japanese Patent Laying-Open No. 2005-116930 discloses a solar cell module with a plurality of cells serially connected to each other, each of which stacked with a substrate, a front electrode formed on the substrate, a power generating layer constituted by the amorphous silicon layer (first photoelectric conversion layer) and the microcrystalline silicon layer (second photoelectric conversion layer) formed on the front electrode, and a back electrode formed on the power generating layer. In such a solar cell module, after forming the power generating layer on the front electrode, grooves dividing the power generating layer with lasers or the like are provided so that the power generating layer is completely separated, the back electrode is provided to fill up the grooves so that the front electrode and the back electrode are connected to each other, and thereafter the back electrode and the power generating layer are separated from each other at prescribed positions, whereby the aforementioned plurality of the cells are serially connected to each other.

In the structure formed by stacking the power generating layer constituted by the amorphous silicon layer and the microcrystalline silicon layer on the front electrode as in the solar cell module described in the Japanese Patent Laying-O pen No. 2005-116930, it has been known in general that the stress is likely to occur on the microcrystalline silicon layer. The adhesion force between the amorphous silicon layer and the front electrode is relatively smaller than the adhesion force between the amorphous silicon layer and the microcrystalline silicon layer.

In the aforementioned solar cell module as in Japanese Patent Laying-Open No. 2005-116930, moisture may penetrate the power generating layer from outside through the grooves dividing the power generating layer. In this case, peeling between the power generating layer and the front electrode is caused by deterioration of the power generating layer due to moisture. In the aforementioned solar cell module as in Japanese Patent Laying-Open No. 2005-116930, the peeing between the power generating layer and the front electrode is disadvantageously caused on an interface between the power generating layer and the front electrode having a relatively small adhesion force due to the stress of the microcrystalline silicon layer constituting the power generating layer when the power generating layer or the front electrode is deteriorated due to the moisture. Thus, reduction in output or the like is disadvantageously caused on a peeling portion.

### SUMMARY OF THE INVENTION

The present invention has been proposed in order to solve the aforementioned problems, and an object of the present invention is to provide a solar cell module capable of suppressing reduction in output.

A solar cell module according to an aspect of the present invention comprises a first cell and a second cell adjacent to each other, each including a first electrode layer, a power generating layer constituted by a first photoelectric conversion layer made of an amorphous silicon layer formed on a surface of the first electrode layer and a second photoelectric conversion layer made of a microcrystalline silicon layer and a second electrode layer formed on a surface of the power generating layer stacked with each other, wherein a first electrode layer of the first cell and a second electrode layer of the second cell are electrically connected to each other, a stress relief region having a thickness smaller than the thickness of overall the power generating layer is formed on a prescribed region of the power generating layer, and the stress relief region is formed in a groove shape so as to extend in a direction substantially perpendicular to a direction for connecting the first cell and the second cell in plan view.

In the solar cell module according to the aspect, as hereinabove described, the stress relief region having the thickness smaller than the thickness of overall the power generating layer is formed on the prescribed region of the power generating layer constituted by the first photoelectric conversion layer made of the amorphous silicon layer and the second photoelectric conversion layer made of the microcrystalline silicon layer, whereby the stress of the power generating layer can be relaxed. Thus, peeling of the first electrode layer and the power generating layer can be suppressed also when the power generating layer or the first electrode layer is deteriorated due to penetration of moisture from outside and hence reduction in output of the solar cell module can be suppressed.

In the aforementioned structure, the stress relief region of the power generating layer is preferably formed in the groove shape in plan view, and the stress relief region is preferably filled up with the second electrode layer. According to this structure, the second electrode layer can inhibit moisture penetrating from outside from reaching the first photoelectric conversion layer and the second photoelectric conversion layer through the stress relief region.

In the aforementioned structure, a plurality of the groove-shaped stress relief regions are preferably formed.

In the aforementioned structure, the plurality of groove-shaped stress relief regions are preferably formed over a substantially whole area of the power generating layer in plan view. According to this structure, the stress of the power generating layer can be relaxed over the whole area and hence peeling between the first electrode layer and the power generating layer can be suppressed.

In the aforementioned structure, the stress relief region is preferably formed at least in the vicinity of a region where the first cell and the second cell are separated from each other in plan view. According to this structure, the region where the stress relief region is formed can be minimized. Thus, reduction in output of the solar cell module caused by forming the stress relief region can be suppressed.

In the aforementioned structure, the stress relief region may be formed in the groove shape so as to extend in the direction substantially perpendicular to the direction for connecting the first cell and the second cell and in a direction substantially parallel to the direction for connecting the first cell and the second cell in the form of a lattice in plan view.

In the aforementioned structure, the stress relief region of the power generating layer may be formed in the groove shape, the second electrode layer may include a first opening region provided on a region corresponding to the stress relief region, and the groove-shaped stress relief region and the first opening region may be filled up with a first insulating member.

In the aforementioned structure, said first opening region may be formed so as to extend in the direction substantially perpendicular to the direction for connecting said first cell and said second cell and not so as to completely divide said second electrode layer in plan view.

In the aforementioned structure, the second photoelectric conversion layer made of the microcrystalline silicon layer may be constituted by a p layer, an i layer and an n layer and formed on an upper surface of the first photoelectric conversion layer, and the stress relief region of the power generating layer may be formed in the groove shape such that the i layer of the second photoelectric conversion layer is partially left.

In the aforementioned structure, the groove-shaped stress relief region may be formed so as to extend up to a position lower than half the thickness of the i layer of the second photoelectric conversion layer.

In the aforementioned structure, the second photoelectric conversion layer made of the microcrystalline silicon layer may be constituted by a p layer, an i layer and an n layer and formed on an upper surface of the first photoelectric conversion layer, and the stress relief region of the power generating layer may be formed in the groove shape so as to pass through the p layer, the i layer and the n layer of the second photoelectric conversion layer.

In the aforementioned structure, the stress relief region of the groove shape may be formed so as to pass through the second photoelectric conversion layer to reach the first photoelectric conversion layer.

In the aforementioned structure, a second insulating member preferably covers an inner surface of the groove-shaped stress relief region passing through the p layer, the i layer and the n layer of the second photoelectric conversion layer. According to this structure, an electrical short circuit between the p layer and the n layer can be suppressed when the groove-shaped stress relief region is filled up with the conductive member.

In the aforementioned structure, the stress relief region of the power generating layer may be formed in the groove shape, and the second electrode layer may include a second opening region provided on a region corresponding to the groove-shaped stress relief region.

In the aforementioned structure, a third insulating member preferably covers an upper surface of the second electrode layer and inner surfaces of the groove-shaped stress relief region and the second opening region. According to this structure, an electrical short circuit between the p layer and the n layer can be suppressed when the groove-shaped stress relief region is filled up with the conductive member.

In the aforementioned structure, the third insulating member preferably has a waterproof function. According to this structure, moisture can be inhibited from penetrating the power generating layer and the first electrode layer located at portions lower than the third insulating member from outside. Thus, the deterioration of the power generating layer or the first electrode layer due to penetration of moisture from outside can be suppressed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a solar cell module according to a first embodiment of the present invention;

FIG. 2 is a perspective view for illustrating the solar cell module shown in FIG. 1 in detail;

FIG. 3 is a plan view of the solar cell module shown in FIG. 2;

FIGS. 4 to 10 are sectional views for illustrating a process of manufacturing the solar cell module shown in FIG. 1;

FIG. 11 is a perspective view shown in a first modification of the first embodiment of the present invention;

FIG. 12 is a plan view showing the solar cell module according to the first modification shown in FIG. 11;

FIG. 13 is a perspective view showing a solar cell module according to a second modification of the first embodiment of the present invention;

FIG. 14 is a plan view showing the solar call module according to the second modification shown in FIG. 13;

FIG. 15 is a perspective view showing a solar cell module according to a third modification of the first embodiment of the present invention;

FIG. 16 is a plan view showing the solar cell module according to the third modification shown in FIG. 15;

FIG. 17 is a sectional view showing a solar cell module according to a second embodiment of the present invention;

FIG. 18 is a perspective view for illustrating the solar cell module according to the second embodiment shown in FIG. 17 in detail;

FIG. 19 is a plan view of the solar cell module shown in FIG. 18;

FIGS. 20 to 22 are sectional views for illustrating a process of manufacturing the solar cell module shown in FIG. 17;

FIGS. 21 and 22 are sectional views for illustrating a process of manufacturing the solar cell module shown in FIG. 17;

FIG. 23 is a plan view showing a solar cell module according to a first modification of the second embodiment of the present invention;

FIG. 24 is a plan view showing a solar cell module of a second modification of the second embodiment of the present invention;

FIG. 25 is a sectional view showing a solar cell module according to a third embodiment of the present invention;

FIGS. 26 to 30 are sectional views for illustrating a process of manufacturing the solar cell module shown in FIG. 25;

FIGS. 26 to 30 are sectional views for illustrating a process of manufacturing of the solar cell module shown in FIG. 25;

FIG. 31 is a sectional view showing a solar cell module according to a fourth embodiment of the present invention; and

FIG. 32 is a sectional view for illustrating a process of manufacturing the solar cell module shown in FIG. 31.

### DESCRIPTION OF THE PREFERRED EMBODIMENTS

Embodiments of the present invention are now described with reference to the drawings.

### First Embodiment

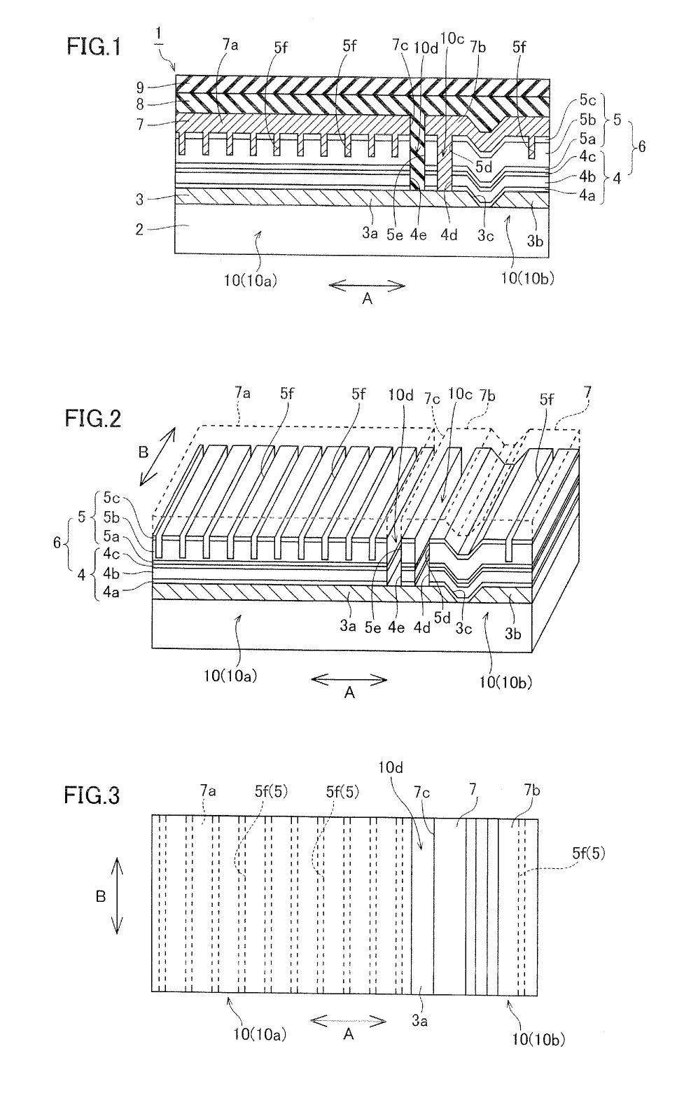

A structure of a solar cell module 1 according to a first embodiment of the present invention will be now described with reference to FIGS. 1 to 3.

As shown in FIG. 1, the solar cell module 1 according to the first embodiment has a tandem structure in which a substrate 2, a front electrode layer 3, a power generating layer 6 constituted by a photoelectric conversion layer 4 and a photoelectric conversion layer 5 formed on a surface of the photoelectric conversion layer 4, a back electrode layer 7, a sealing resin 8 and a back sheet 9 are stacked. The tandem structure is a structure of the solar cell module formed for improving photoelectric conversion efficiency by combining different kinds of semiconductor thin films (semiconductor thin films having different bands of absorption wavelengths respectively). According to the first embodiment, the front electrode layer 3, the power generating layer 6 and the back electrode layer 7 constitute a cell 10. The front electrode layer 3 and the back electrode layer 7 are examples of the “first electrode layer” and the “second electrode layer” in the present invention respectively. A cell 10a and a cell 10b adjacent to the cell 10a are serially connected with each other by electrically connecting a front electrode layer 3a of the cell 10a and a back electrode layer 7b of the cell 10b through a groove 10c completely separating the power generating layer 6. The cell 10a and the cell 10b are examples of the “first cell” and the “second cell” in the present invention respectively. The cell 10a is separated into the cell 10a and the cell 10b through a groove 10d dividing the power generating layer 6 and the back electrode layer 7. The cell 10 has a width of about 1 cm in a direction A and a length of about 1.2 m in a direction B. The hundred cells 10 are serially connected each other in the direction A, thereby constituting a solar cell module having a width of about 1 m in the direction A and a length of about 1.2 m in the direction B. The detailed structure of the solar cell module 1 according to the first embodiment will be hereinafter described.

The substrate 2 has an insulating surface and is made of translucent glass. This substrate 2 has a thickness of about 1 mm to about 5 mm. The front electrode layers 3a and 3b separated through a groove portion 3c is formed on an upper surface of the substrate 2. The front electrode layers 3a and 3b, each having a thickness of about 800 nm, are made of TCO (transparent conductive oxide) such as tin oxide (SnO₂) having conductivity and translucency.

The photoelectric conversion layer 4 made of a p-i-n amorphous silicon semiconductor is formed on upper surfaces of the front electrode layers 3a and 3b. This photoelectric conversion layer 4 made of the p-i-n amorphous silicon semiconductor is constituted by a p-type hydrogenated amorphous silicon carbide (a-SiC: H) layer 4a (hereinafter referred to as a p layer 4a) having a thickness of about 10 nm an i-type hydrogenated amorphous silicon (a-Si: H) layer 4b (hereinafter referred to as an i layer 4b) having a thickness of about 300 nm and an n-type hydrogenated amorphous silicon layer 4c (hereinafter referred to as an i layer 4b) having a thickness of about 20 nm. The photoelectric conversion layer 4 is formed on the upper surface of the front electrode layer 3a to have groove portions 4d and 4e and fill up the groove portion 3c. The photoelectric conversion layer 4 made of the amorphous silicon semiconductor is formed for absorbing light of a relatively short wavelength.

The photoelectric conversion layer 5 of a p-i-n microcrystalline silicon semiconductor is formed on an upper surface of the photoelectric conversion layer 4. This photoelectric conversion layer 5 of the p-i-n microcrystalline silicon semiconductor is constituted by a p-type hydrogenated microcrystalline silicon (μc-Si: H) layer 5a (hereinafter referred to as a p layer 5a) having a thickness of about 10 nm, an i-type hydrogenated microcrystalline silicon layer 5b (hereinafter referred to as an i layer 5a) having a thickness of about 2000 nm and an n-type hydrogenated microcrystalline silicon layer 5c (hereinafter referred to as an n layer 5c) having a thickness of about 20 nm. The photoelectric conversion layer 5 has groove portions 5d and 5e on regions corresponding to the groove portions 4d and 4e respectively. The photoelectric conversion layer 5 of the p-i-n microcrystalline silicon semiconductor is formed for absorbing light of a relatively long wavelength.

According to the first embodiment, ten stress relief grooves 5f extending in the direction B are formed on the photoelectric conversion layer 5 at substantially equal intervals (about 1 mm pitch) in the direction A, as shown in FIGS. 1 to 3. The stress relief grooves 5f each have a width of about 50 μm. These stress relief grooves 5f are so formed as to extend over the whole area of the power generating layer 6 in the direction B (direction perpendicular to a direction for connecting the cells 10a and 10b) substantially parallel to the groove 10c (groove portions 4d and 5d) and the groove 10d (groove portions 4e, 5e and 7c). The stress relief grooves 5f are so formed as to pass through the n layer 5c from an upper side of the photoelectric conversion layer 5 and lower portions of the layer 5b are partially left. In other words, the thickness of a portion where each stress relief groove 5f is formed is smaller than the thickness of the overall power generating layer 6. The stress relief grooves 5f are examples of the “stress relief regions” in the present invention.

The back electrode layer 7a of the cell 10a and the back electrode layer 7b of the cell 10b separating from each other by the groove portion 7c formed on the regions corresponding to the groove portions 4e and 5e are formed on an upper surface of the power generating layer 6 (photoelectric conversion layer 5). The groove portions 7c, 4e and 5e constitute the groove 10d separating the cells 10a and 10b from each other. The back electrode layers 7a and 7b are formed by holding a silver (Ag) layer between ZnO layers. The lower ZnO layer, the Ag layer and the upper ZnO layer have the thicknesses of about 100 nm, about 200 nm and about 45 nm respectively and have a thickness of about 345 nm as a whole. The back electrode layer 7b fills up the groove 10c constituted by the groove portions 4d and 5d and the stress relief grooves 5f. These back electrode layers 7a and 7b have a function of reflecting light incident from the lower surface of the substrate 2 to reach the back electrode layers 7a and 7b thereby reintroducing the same into the photoelectric conversion layers 4 and 5.

The sealing resin 8 made of EVA (ethylene-vinyl acetate) is formed on an upper surface of the back electrode layer 7. This sealing resin 8 fills up the groove 10d (groove portions 4e, 5e and 7c). The back sheet 9 made of PET (polyethylene terephthalate) is formed on an upper surface of the sealing resin 8.

A process of manufacturing of the solar cell module 1 according to the first embodiment of the present invention will be now described with reference to FIGS. 1 and 4 to 10.

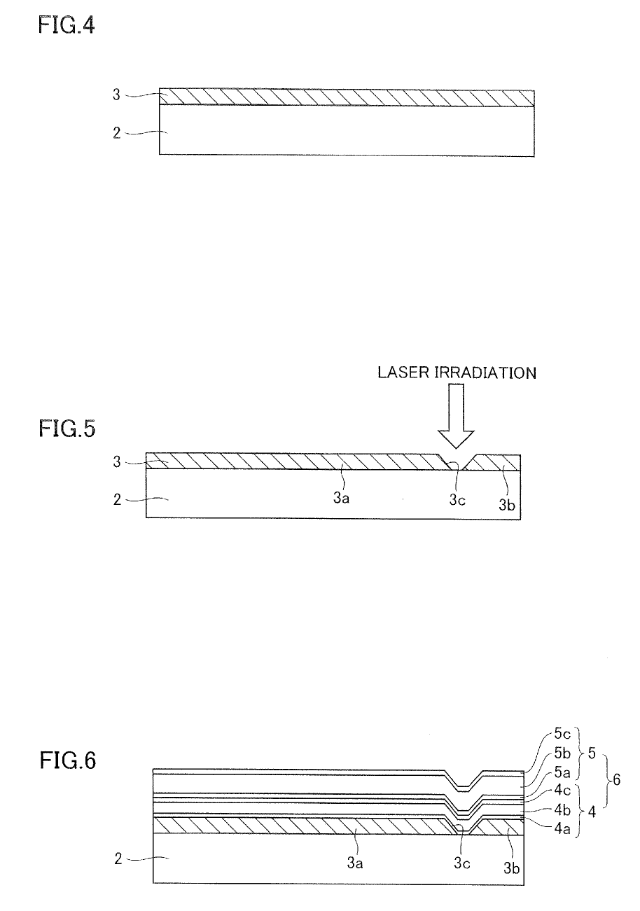

As shown in FIG. 4, the front electrode layer 3 made of tin oxide having a thickness of about 800 nm is formed on the insulating surface or the substrate 2 by thermal CVD (chemical vapor deposition).

As shown in FIG. 5, the groove portion 3c is formed by scanning the front electrode layer 3 with a fundamental wave of an Nd:YAG laser having a wavelength of about 1.06 μm, an oscillation frequency of about 3 kHz and average power of about 10 W from above. Thus, the front electrode layer 3 is separated into the front electrode layers 3a and 3b through the groove portion 3c.

As shown in FIG. 6, the photoelectric conversion layer 4 of the amorphous silicon semiconductor is formed by successively forming the p layer (p-type hydrogenated amorphous silicon carbide layer) 4a having a thickness of about 10 nm, the i layer (i-type hydrogenated amorphous silicon layer) 4b having the thickness of about 300 nm and the n layer (n-type hydrogenated amorphous silicon layer) having the thickness of about 20 nm on the upper surfaces of the front electrode layers 3a and 3b by plasma CVD. Then, the photoelectric conversion layer 5 of the microcrystalline silicon semiconductor is formed by successively forming the p layer (p-type hydrogenated microcrystalline silicon layer) 5a having a thickness of about 10 nm, the i layer (i-type hydrogenated microcrystalline silicon layer) 5b having a thickness of about 2000 nm and the n layer (n-type hydrogenated microcrystalline silicon layer) 5c having a thickness of about 20 nm on the upper surface of the photoelectric conversion layer 4 by plasma CVD. Table 1 shows the film forming conditions in this case.

TABLE 1

| | Substrate | Gas Flow | Reaction | | Film |
|---|---|---|---|---|---|
| | Temperature | Rate | Pressure | PF Power | Thickness |
| | (° C.) | (sccm) | (Pa) | (W) | (nm) |
| P layer | 180 | SiH₄: 300 | 106 | 10 | 10 |
| (a-SiC: | | CH₄: 300 | | | |
| H) | | H₂: 2000 | | | |
| | | B₂H₆: 3 | | | |
| I layer | 200 | SiH₄: 300 | 106 | 20 | 300 |
| (a-Si: H) | | H₂: 2000 | | | |
| N layer | 180 | SᵢH₄: 300 | 133 | 20 | 20 |
| (a-Si: H) | | H₂: 2000 | | | |
| | | PH₃: 5 | | | |
| P layer | 180 | SᵢH₄: 10 | 106 | 10 | 10 |
| (μc-Si: | | H₂: 2000 | | | |
| H) | | B₂H₆: 3 | | | |
| I layer | 200 | SᵢH₄: 100 | 133 | 20 | 2000 |
| (μc-Si: | | H₂: 2000 | | | |
| H) | | | | | |
| N layer | 200 | SᵢH₄: 10 | 133 | 20 | 20 |
| (μc-Si: | | H₂: 2000 | | | |
| H) | | PH₃: 5 | | | |

As shown in Table 1, the p layer 4a of the photoelectric conversion layer 4 is formed with a thickness of 10 nm under the following conditions:

substrate temperature: 180° C.

gas flow rates of SiH₄, CH₄, H₂ and B₂H₆: 300 sccm, 300 sccm, 2000 sccm, and 3 sccm

reaction pressure: 106 Pa

RF (radio frequency) power: 10 W

The i layer 4b of the photoelectric conversion layer 4 is formed with a thickness of 300 nm under the following conditions:

substrate temperature: 200° C.

gas flow rates of SiH₄ and H₂: 300 sccm and 2000 sccm

reaction pressure: 106 Pa

RF power: 20 W

The n layer 4c of the photoelectric conversion layer 4 is formed with a thickness of 20 nm under the following conditions:

substrate temperature: 180° C.

gas flow rates of SiH₄, H₂ and PH₃: 300 sccm, 2000 sccm and 5 sccm

reaction pressure: 133 Pa

RF power: 20 W

The p layer 5a of the photoelectric conversion layer 5 is formed with a thickness of 10 nm under the following conditions:

substrate temperature: 180° C.

gas flow rates of SiH₄, H₂ and B₂H₆: 10 sccm, 2000 sccm and 3 sccm

reaction pressure: 106 Pa

RF power: 10 W

The i layer 5b of the photoelectric conversion layer 5 is formed with a thickness of 2000 nm under the following conditions:

substrate temperature: 200° C.

gas flow rates of SiH₄ and H₂: 100 sccm and 2000 sccm

reaction pressure: 133 Pa

RF power: 20 W

The n layer 5c of the photoelectric conversion layer 5 is formed with a thickness of 20 nm under the following conditions:

substrate temperature: 200° C.

gas flow rates of SiH₄, H₂ and PH₃: 10 sccm, 2000 sccm and 5 sccm

reaction pressure: 133 Pa

RF power: 20 W

Thus, the power generating layer 6 constituted by the photoelectric conversion layers 4 and 5 is formed.

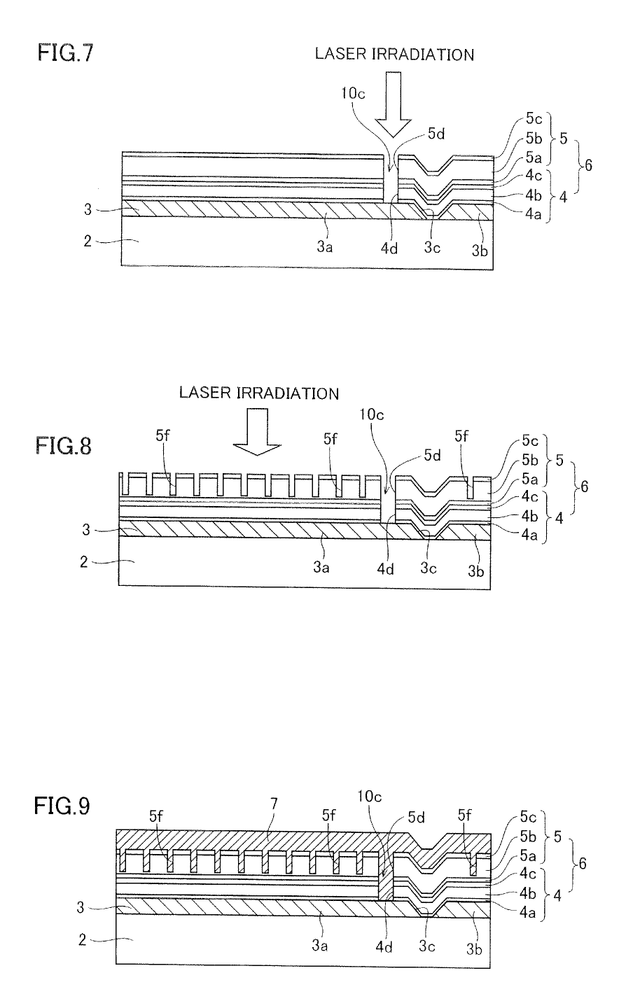

As shown in FIG. 7, the groove 10c constituted by the groove portions 4d and 5d is formed in the vicinity of the groove portion 3c on the side of the front electrode layer 3 by scanning the vicinity of the groove portion 3c on the side of the front electrode layer 3 with a fundamental wave of an Nd:YAG laser having a wavelength of about 1.06 μm, an oscillation frequency of about 3 kHz and average power of about 7 W from above. Thus, the power generating layer 6 constituted by the photoelectric conversion layers 4 and 5 is completely separated.

According to the first embodiment, a plurality of the stress relief grooves 5f extending substantially parallel to the groove portions 4d and 5d are formed by applying a laser, as shown in FIG. 80. A relatively short wavelength (about 355 nm or about 248 nm, for example) easily absorbed in the microcrystalline silicon layer and allowing a shallow laser penetration depth is employed as the wavelength of the laser for forming these stress relief grooves 5f. The photoelectric conversion layer 5 is removed from above such that the p layer 4c of the photoelectric conversion layer 4 is not exposed and the i layer 5b (thickness: about 2000 nm) having the largest thickness among the photoelectric conversion layer 5 is partially left with a thickness of about 200 nm or more, thereby forming stress relief grooves 5f.

Thereafter the back electrode layer 7 made of metal material layer (ZnO layer (upper layer)/Ag layer (intermediate layer)/ZnO layer (lower layer)) mainly composed of silver is formed on the upper surface of the photoelectric conversion layer 5 by sputtering as shown in FIG. 9. At this time, the back electrode layer 7 fills up the groove 10c (groove portions 4d and 5d) and the stress relief grooves 5f. The back electrode layer 7 fills up the groove 10c so that the back electrode layer 7 and the front electrode layer 3 are electrically connected to each other.

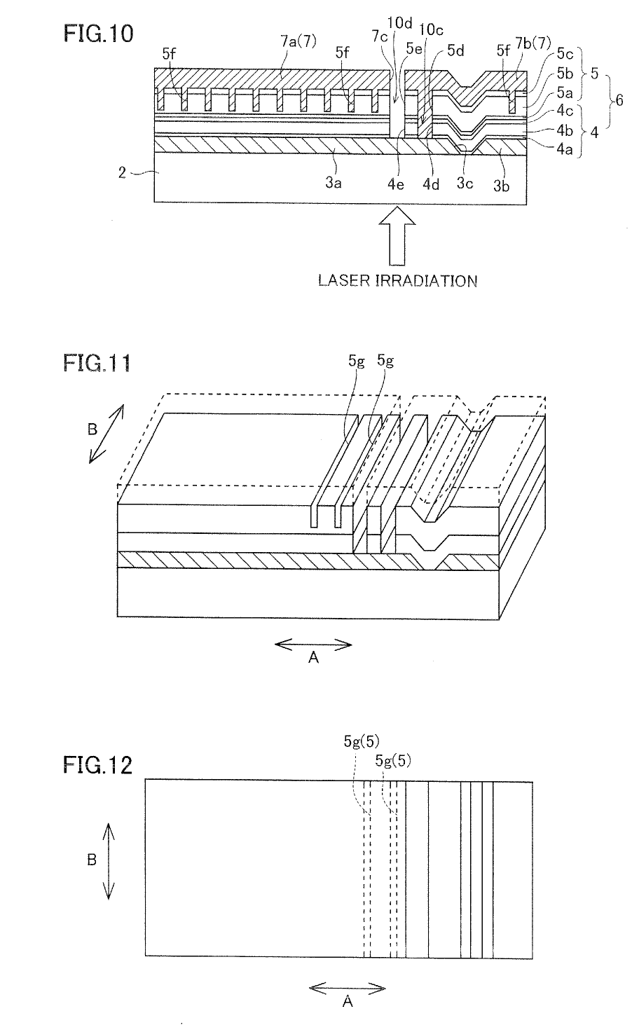

As shown in FIG. 10, the groove 10d constituted by the groove portions 4e, 5e and 7c is formed in the vicinity opposite to the groove portion 3c with respect to the groove 10c (groove portions 4d and 5d) by scanning the vicinity opposite to the groove portion 3c with respect to the groove 10c with a second harmonic of an Nd:YAG laser having a wavelength of about 532 nm, an oscillation frequency of about 4 kHz and average power of about 7 W from the side of the substrate 2. Thus, the back electrode layer 7 is separated into the back electrode layers 7a and 7b through the groove portion 7c. Then, vacuum heating/pressure-bonding is performed at 150° C. with a laminating machine (thermocompression device), and the sealing resin 8 made of EVA and the back sheet 9 made of PET are sequentially stacked on surfaces of the back electrode layers 7a and 7b. At this time, the sealing resin 8 fills up the groove 10d (groove portions 4e, 5e and 7c). Thus, the solar cell module 1 according to the first embodiment is formed as shown in FIG. 1.

According to the first embodiment, as hereinabove described, the plurality of stress relief grooves 5f extending in the direction B are formed on the power generating layer 6, whereby the stress of the photoelectric conversion layer 5 made of the microcrystalline silicon layer can be relaxed. Thus, peeling of the front electrode layer 3 and the photoelectric conversion layer 4 can be suppressed also when the power generating layer 6 (photoelectric conversion layers 4 and 5) or the front electrode layer 3 is deteriorated due to penetration of moisture from outside through the groove 10d constituted by the groove portions 4e, 5e and 7c, and hence appearance abnormality and reduction in output of the solar cell module 1 can be suppressed.

According to the first embodiment, as hereinabove described, the back electrode layer 7 fills up the stress relief grooves 5f, whereby the back electrode layer 7 can inhibit moisture penetrating from outside from reaching the photoelectric conversion layers 4 and 5 through the stress relief grooves 5f dissimilarly to a case where the sealing resin 8 fills up the stress relief grooves 5f.

According to the first embodiment, as hereinabove described, the stress relief grooves 5f are so formed as to extend in the direction (direction B) substantially perpendicular to the direction (direction A) for connecting the cells 10a and 10b to each other in plan view, whereby stress can be relaxed over the whole area in the direction B and hence peeling of the photoelectric conversion layer 4 from the front electrode layer 3 can be effectively suppressed.

According to the first embodiment, as hereinabove described, the stress relief grooves 5f are formed by removing the i layer 5b of the photoelectric conversion layer 5 constituted by the p layer 5a, the i layer 5b and the n layer 5c in a thickness direction from above so as to partially leave the same, whereby the depth of removing the i layer 5b having relatively large thickness can be controlled and hence the stress relief grooves 5f can be inhibited from reaching the p layer 5a of the photoelectric conversion layer 5 when forming the stress relief grooves 5f. Thus, an electrical short circuit between the p layer 5a and the n layer 5c through the back electrode layer 7 filling up the stress relief grooves can be suppressed dissimilarly to a case where the stress relief grooves 5f reach the p layer 5a.

In a solar cell module according to a first modification of the first embodiment, stress relief grooves 5g are formed in the vicinity of groove portions 4e, 5e and 7c (region separating cells 10a and 10b), as shown in FIGS. 11 and 12. In other words, the region in the vicinity of the groove 10d (groove portions 4e, 5e and 7c) as a path through which moisture penetrates from outside is likely to be deteriorated due to moisture of power generating layer 6, and hence the stress of the portion in the vicinity of the groove 10d, which is likely to be deteriorated, is relaxed with the stress relief grooves 5g and hence the stress can be effectively relaxed while the areas of regions where the stress relief grooves 5g are formed can be minimized. Thus, reduction in output of a solar cell module 1 caused by forming the stress relief grooves 5g can be suppressed while appearance abnormality and reduction in output due to peeling of the power generating layer 6 from a front electrode layer 3 can be suppressed.

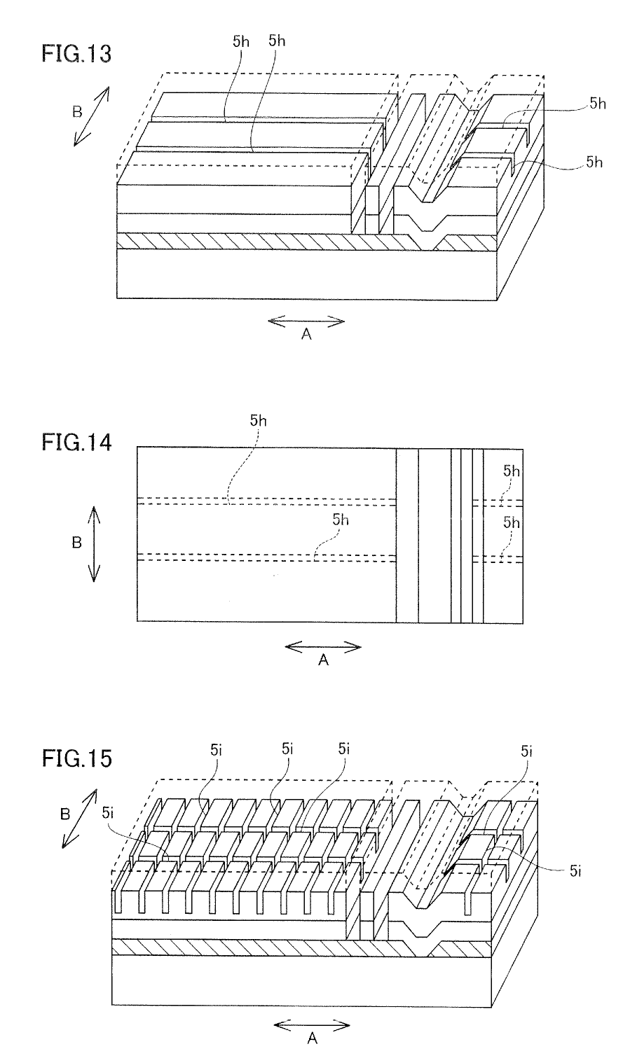

In a solar cell module according to a second modification of the first embodiment, stress relief grooves 5h are so formed as to extend in a direction A (direction for connecting cells 10a and 10b) as shown in FIGS. 13 and 14. Also according to this structure, the stress of a photoelectric conversion layer 5 can be relaxed and hence appearance abnormality and reduction in output can be suppressed.

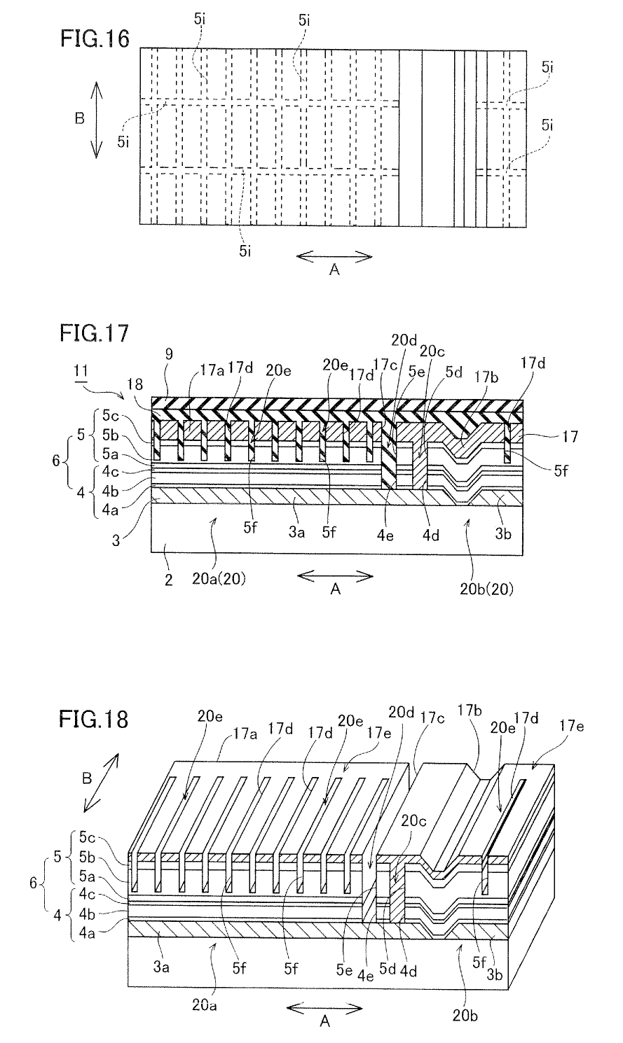

In a solar cell module according to a third modification of the first embodiment, the stress relief grooves 5i are so formed as to extend in both of a directions A and B as shown in FIGS. 15 and 16. According to this structure, the stress of the photoelectric conversion layer 5 can be further relaxed as compared with the aforementioned first embodiment and the second and first modifications.

### Second Embodiment

According to a second embodiment, stress relief grooves are formed over a power generating layer and a back electrode layer dissimilarly to the solar cell module formed with the stress relief grooves only on the power generating layer according to the aforementioned first embodiment. A structure of a solar cell module 11 according to the second embodiment will be now described with reference to FIGS. 17 to 19.

As shown in FIG. 17, the solar cell module 11 according to the second embodiment has a structure in which a substrate 2, a front electrode layer 3, a power generating layer 6 constituted by a photoelectric conversion layer 4 and a photoelectric conversion layer 5 formed on a surface of the photoelectric conversion layer 4, a back electrode layer 17, a sealing resin 18 and a back sheet 9 are stacked. The solar cell module 11 has a structure in which a plurality of cells 20 (cells 20a and 20b) are serially connected to each other. The back electrode layer 17, the cell 20a and the cell 20b are examples of the “second electrode layer”, the “first cell” and the “second cell” in the present invention respectively. The photoelectric conversion layer 5 is formed with stress relief grooves 5f similarly to the aforementioned first embodiment.

The back electrode layer 17 according to the second embodiment is separated into a back electrode layer 17a on a side of the cell 20a and a back electrode layer 17b on a side of the cell 20b through a groove portion 17c. A front electrode layer 3a of the cell 20a and the back electrode layer 17b of the cell 20b are electrically connected to each other through a groove 20c constituted by a groove portion 4d of the photoelectric conversion layer 4 and a groove portion 5d of the photoelectric conversion layer 5. The cell 20 is separated into the cells 20a and 20b through a groove 20d constituted by a groove portion 4e of the photoelectric conversion layer 4, a groove portion 5e of the photoelectric conversion layer 5 and the groove portion 17c of the back electrode layer 17.

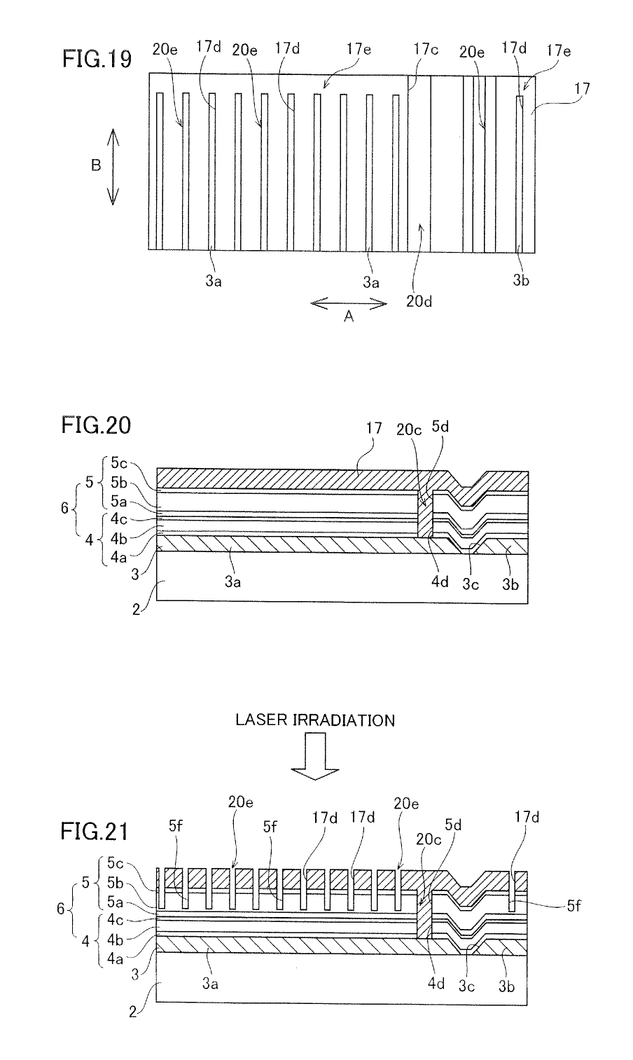

According to the second embodiment, a plurality of groove portions 17d are formed on regions of the back electrode layer 17 corresponding to the stress relief grooves 5f are formed. The groove portions 17d and the stress relief grooves 5f constitute the stress relief grooves 20e. The groove portions 17d are examples of the “first opening regions” in the present invention and the stress relief grooves 20e are examples of the “stress relief regions” in the present invention. These groove portions 17d (stress relief grooves 20e) are so formed as to extend in a direction B (direction perpendicular to a direction for connecting the cells 20a and 20b) substantially parallel to the groove 20c (groove portions 4d and 5d) and the groove 20d (groove portions 4e, 5e and 17c). As shown in FIGS. 18 and 19, the back electrode layer 17 has a region 17e where no groove 17d is formed such that the back electrode layers 17a and 17b are electrically separated from each other through the groove portions 17d. The stress relief grooves 20e are filed up with the sealing resin 18. The sealing resin 18 is an example of the “second insulating member” in the present invention.

The remaining structure of the solar cell module 11 according to the second embodiment is similar to that of the solar cell module 1 according to the aforementioned first embodiment and hence the description thereof is not repeated.

A process of manufacturing the solar cell module 11 according to the second embodiment of the present invention will be now described with reference to FIGS. 17 and 20 to 22.

According to the second embodiment, the front electrode layer 3 (front electrode layers 3a and 3b) and the photoelectric conversion layers 4 and 5 are formed on an upper surface of the substrate 2 and the groove 20c constituted by the groove portions 4d and 5d are formed by laser irradiation by a process of manufacturing similar to that shown in FIGS. 4 to 7 of the aforementioned first embodiment, as shown in FIG. 20. According to the second embodiment thereafter the back electrode layer 17 is formed on an upper surface of the photoelectric conversion layer 5 (power generating layer 6) as shown in FIG. 20.

As shown in FIG. 21, patterning is performed so as to pass through the back electrode layer 17 from above and partially leave an i layer 5b of the photoelectric conversion layer 5 made of the microcrystalline silicon layer by applying lasers from a side of a film surface. Thus, the stress relief grooves 20e constituted by the groove portions 17d of the back electrode layer 17 and the stress relief grooves 5f of the photoelectric conversion layer 5 are formed.

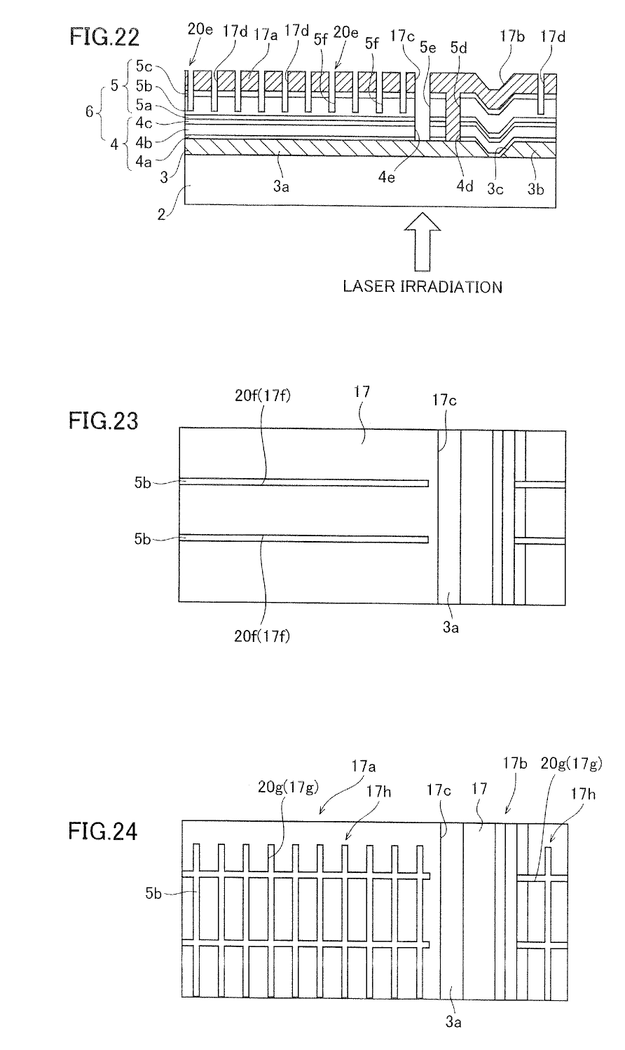

Thereafter the groove 20d constituted by the groove portions 4e, 5e and 17c is formed in the vicinity opposite to the groove portion 3c with respect to the groove 20c (groove portions 4d and 5d) by applying a laser to the vicinity opposite to the groove portion 3c with respect to the groove 20c as shown in FIG. 22. Thus, the back electrode layer 17 is separated into the back electrode layers 17a and 17b through the groove portion 17c.

As shown in FIG. 17, the sealing resin 18 is so formed on an upper surface of the back electrode layer 17 as to fill up the groove 20d (groove portion 4e, 5e and 17c) and the stress relief grooves 20e (stress relief grooves 5f and the groove portions 17d). Thereafter the back sheet 9 is formed on an upper surface of the sealing resin 18, thereby forming the solar cell module 11 according to the second embodiment.

According to the second embodiment, as hereinabove described, the stress relief grooves 20e constituted by the stress relief grooves 5f of the photoelectric conversion layer 5 and the groove portions 17d of the back electrode layer 17 are formed, whereby not only the stress of the power generating layer 6 but also the stress of the back electrode layer 17 can be relaxed, and hence appearance abnormality and reduction in output can be further suppressed of the solar cell module 11 as compared with the solar cell module formed with the stress relief grooves 5f only on the photoelectric conversion layer 5 according to the aforementioned first embodiment.

The remaining effects of the solar cell module according to the second embodiment are similar to those of the solar cell module according to the aforementioned first embodiment.

In a solar cell module according to a first modification of the second embodiment, groove portions 17f (stress relief grooves 20f) are so formed as to extend in a direction A as shown in FIG. 23. In a solar cell module according to a second modification of the second embodiment, groove portions 17g (stress relief grooves 20g) are so formed as to extend in both of directions A and B as shown in FIG. 24. According to a second modification of the second embodiment, the back electrode layer 17 has a region 17h where no groove 17g is formed such that back electrode layers 17a and 17b are electrically separated from each other through the stress relief grooves 20g. The solar cell modules according to these structures can also obtain the effects similar to those of the solar cell modules according to the aforementioned second embodiment.

### Third Embodiment

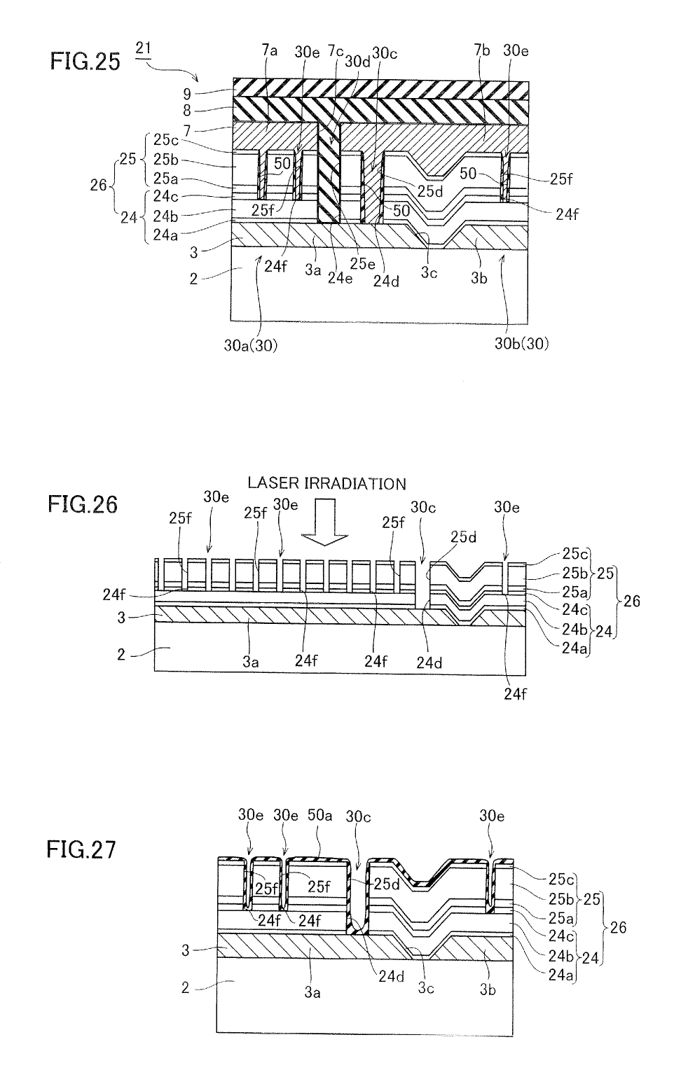

According to a third embodiment, stress relief grooves formed on a power generating layer are formed so as to pass through a photoelectric conversion layer made of microcrystalline silicon to reach a photoelectric conversion layer made of amorphous silicon in the structure of the aforementioned first embodiment. A structure of a solar cell module 21 according to a third embodiment will be now described with reference to FIG. 25.

As shown in FIG. 25, the solar cell module 21 according to the third embodiment has a structure in which a substrate 2, a front electrode layer 3, a power generating layer 26 constituted by a photoelectric conversion layer 24 made of an amorphous silicon layer and a photoelectric conversion layer 25 made of a microcrystalline silicon layer formed on a surface of the photoelectric conversion layer 24, a back electrode layer 7, a sealing resin 8 and a back sheet 9 are stacked. The photoelectric conversion layer 24 is constituted by a p layer 24a, an i layer 24b and an n layer 24c, and the photoelectric conversion layer 25 is constituted by a p layer 25a, an i layer 25b and an n layer 25c. The solar cell module 21 has a structure in which a plurality of cells 30 (cells 30a and 30b) are serially connected to each other. The cell 30a and the cell 30b are examples of the “first cell” and the “second cell” in the present invention respectively.

The photoelectric conversion layer 24 of the solar cell module 21 according to the third embodiment includes groove portions 24d and 24e and the photoelectric conversion layer 25 includes groove portions 25d and 25e. A groove 30c for electrically connecting the cells 30a and 30b is formed by the groove portions 24d and 25d. A groove 30d for separating the cells 30a and 30b is formed by the groove portions 24e, 25e and 7c,

According to the third embodiment, a plurality of stress relief grooves 30e are formed on the power generating layer 26 so as to pass through the photoelectric conversion layer 25 from above and partially leave the photoelectric conversion layer 24. The stress relief grooves 30e are examples of the “stress relief regions” in the present invention. The stress relief grooves 30e are constituted by groove portions 24f of the photoelectric conversion layer 24 and groove portions 25f of the photoelectric conversion layer 25. Side wall insulating films 50 made of SiN or the like cover both side surfaces of the groove 30c and the stress relief grooves 30e. These side wall insulating films 50 inhibit inner surfaces of the groove 30c and the stress relief grooves 30e of the power generating layer 26 from being in contact with the back electrode layer 7, and penetration of moisture in the power generating layer 26 can be suppressed. The side wall insulating films 50 are examples of the “second insulating members” in the present invention.

The remaining structure of the solar cell module 21 according to the third embodiment is similar to that of the solar cell module 1 according to the aforementioned first embodiment and hence the description thereof is not repeated.

A process of manufacturing the solar cell module 21 according to the third embodiment of the present invention will be now described with reference to FIGS. 25 to 30.

According to the third embodiment, the stress relief grooves 30e are formed by irradiating a laser through the manufacturing process shown in FIG. 4 to 7 of the aforementioned first embodiment, as shown in FIG. 26.

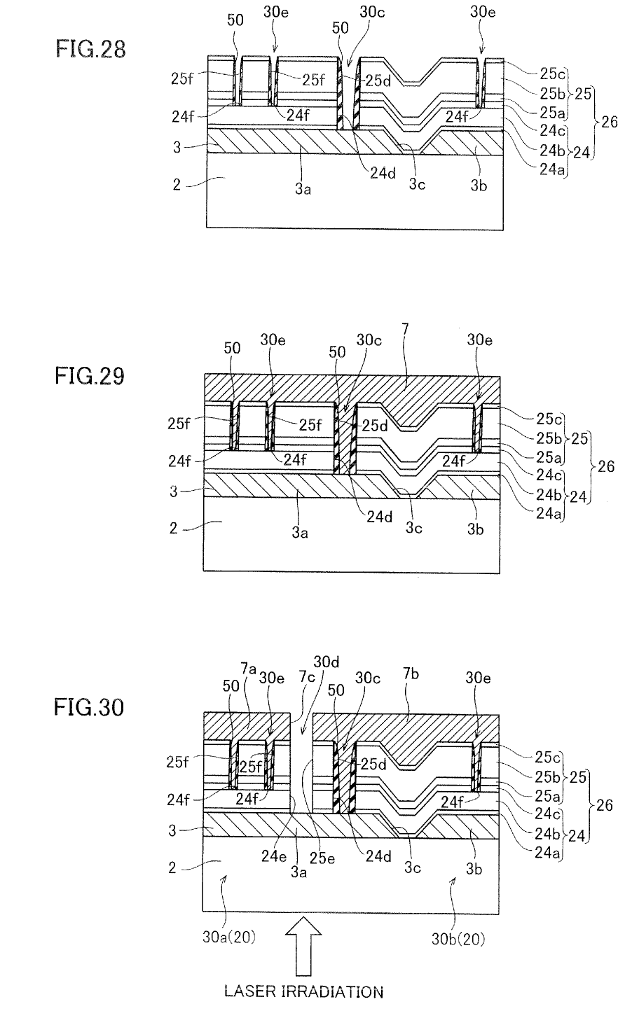

An insulating film 50a made of SiN or the like is formed on an upper surface of the photoelectric conversion layer 25 by CVD as shown in FIG. 27. Thereafter the insulating film 50a on the photoelectric conversion layer 25 is removed by laser patterning or etching is performed by anisotropic etching (RIE (reactive ion etching)) until no insulating film 50a on the photoelectric conversion layer 25 remains, thereby forming the side wall insulating films 50 on the both side surfaces of the groove 30c and 30d, as shown in FIG. 28.

As shown in FIG. 29, the back electrode layer 7 is so formed as to fill up the grooves 30c and 30d formed with the side wall insulating films 50. Then the groove 30d constituted by the groove portions 24e, 25e and 7c are formed in the vicinity opposite to the groove portion 3c with respect to the groove 30c by applying a laser to the vicinity opposite to the groove portion 3c with respect to the groove 30c as shown in FIG. 30. Thus, the back electrode layer 7 is separated into the back electrode layers 7a and 7b through the groove portion 7c.

As shown in FIG. 25, the sealing resin 8 is so formed on an upper surface of the back electrode layer 7 as to fill up the stress relief grooves 30e. Thereafter the back sheet 9 is formed on an upper surface of the sealing resin 8, thereby forming the solar cell module 21 according to the third embodiment.

According to the third embodiment, as hereinabove described, the plurality of stress relief grooves 30e formed so as to pass through the photoelectric conversion layer 25 from above and partially leave the photoelectric conversion layer 24 are provided on the power generating layer 26, whereby the thickness of the portion, where each stress relief groove 30e is formed, of the power generating layer 26, can be smaller than that of the aforementioned first embodiment, and hence the stress of the power generating layer 26 can be relaxed. Thus, appearance abnormality of the solar cell module 21 and reduction in output can be further effectively suppressed as compared with the solar cell module according to the aforementioned first embodiment.

### Fourth Embodiment

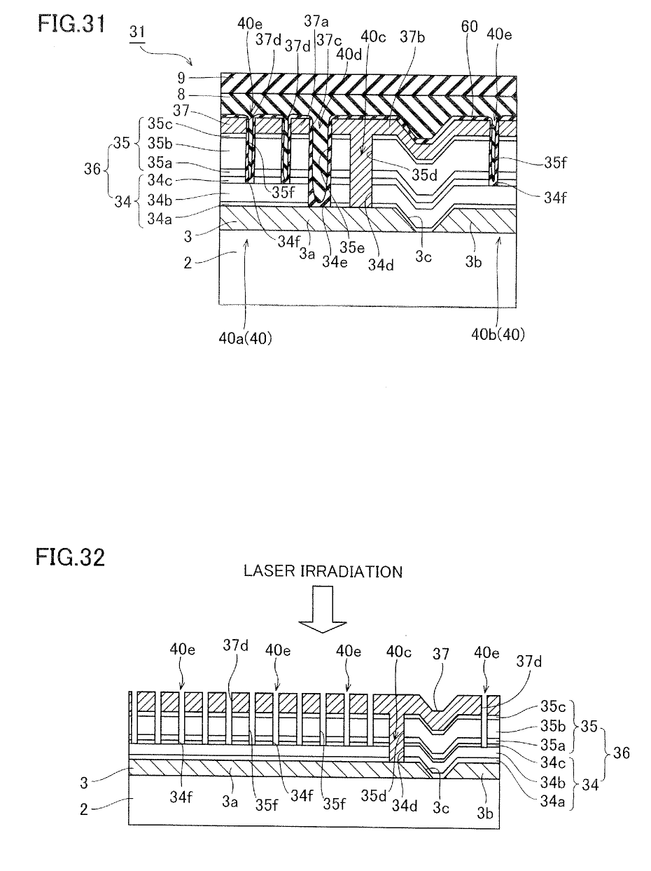

According to a fourth embodiment, stress relief grooves formed on a power generating layer are formed so as to pass through a photoelectric conversion layer made of microcrystalline silicon to reach a photoelectric conversion layer made of amorphous silicon in the structure of the aforementioned second embodiment. A structure of a solar cell module 31 according to a fourth embodiment will be now described with reference to FIG. 31.

The solar cell module 31 according to the fourth embodiment has a structure in which a substrate 2, a front electrode layer 3, a power generating layer 36 constituted by a photoelectric conversion layer 34 made of an amorphous silicon layer and a photoelectric conversion layer 35 made of a microcrystalline silicon layer formed on a surface of the photoelectric conversion layer 34, a back electrode layer 37, a sealing resin 8 and a back sheet 9 are stacked. The back electrode layer 37 is an example of the “second electrode layer” in the present invention. The photoelectric conversion layer 34 is constituted by a p layer 34a, an i layer 34b and an n layer 34c, and the photoelectric conversion layer 35 is constituted by a p layer 35a, an i layer 35b and an n layer 35c. The solar cell module 31 has a structure in which a plurality of cells 40 (cells 40a and 40b) are serially connected to each other. The cell 40a and the cell 40b are examples of the “first cell” and the “second cell” in the present invention respectively.

The photoelectric conversion layer 34 of the solar cell module 31 according to the fourth embodiment includes groove portions 34d and 34e and the photoelectric conversion layer 35 includes groove portions 35d and 35e. A groove 40c for electrically connecting the cells 40a and 40b is formed by the groove portions 34d and 35d. A groove 40d for separating the cells 40a and 40b is formed by the groove portions 34e and 35e and a groove portion 37c separating the back electrode layer 37 into back electrode layers 37a and 37b.

According to the fourth embodiment, a plurality of stress relief grooves 40e are formed on the power generating layer 36 so as to pass through the back electrode layer 37 (back electrode layer 37a) and the photoelectric conversion layer 35 from above and partially leave the photoelectric conversion layer 34. The stress relief grooves 40e are examples of the “stress relief regions” in the present invention. The stress relief grooves 40e are constituted by groove portions 34f and 35f of the photoelectric conversion layers 34 and 35 and groove portions 37d of the back electrode layer 37. The groove portions 37d are examples of the “second opening regions” in the present invention. An insulating layer 60 made of SiN or the like cover an upper surface of the back electrode layer 37 and inner surfaces of the groove 40d and the stress relief grooves 40e. The insulating layer 60 is an example of the “third insulating member” in the present invention. This insulating layer 60 inhibits moisture from penetrating the power generating layer 36 or the front electrode layer 3 from outside. The back electrode layer 37 has a region (not shown) where no stress relief groove 40e is formed so as to electrically separate the back electrode layer 37, similarly to the aforementioned second embodiment. The remaining structure of the solar cell module 31 according to the fourth embodiment is similar to that of the solar cell module 21 according to the aforementioned second embodiment and hence the description thereof is not repeated.

A process of manufacturing the solar cell module 31 according to the fourth embodiment of the present invention will be now described with reference to FIGS. 31 and 32.

According to the fourth embodiment, the back electrode layer 37 is formed on an upper surface of the photoelectric conversion layer 35 (power generating layer 36) by a manufacturing process similar to that shown in FIGS. 4 to 7 of the aforementioned first embodiment and FIG. 20 of the aforementioned second embodiment. As shown in FIG. 32, the plurality of stress relief grooves 40e are formed by a laser. Thereafter the groove 40d for isolating the back electrode layer 37 and the power generating layer 36 are formed by a laser. Then a SiN layer or the like is stacked so as to cover the upper surface of the back electrode layer 37 and the inner surfaces of the grooves 40d and 40e by CVD, sputtering, evaporation or the like, thereby forming the insulating layer 60. Thereafter the sealing resin 8 is so formed on the insulating layer 60 as to fill up the grooves 40d and 40e, as shown in FIG. 31. Thereafter the back sheet 9 is formed on an upper surface of the sealing resin 8, thereby forming the solar cell module 31 according to the fourth embodiment.

According to the fourth embodiment, as hereinabove described, the plurality of stress relief grooves 40e formed so as to pass through the back electrode layer 37 and the photoelectric conversion layer 35 from above and partially leave the photoelectric conversion layer 34 are provided, whereby the thickness of the portion, where each stress relief groove 30e is formed, of the power generating layer 36 can be smaller than that of the aforementioned second embodiment and hence the stress of the power generating layer 36 can be further relaxed. Thus, appearance abnormality and reduction in output of the solar cell module 31 can be further effectively suppressed as compared with the solar cell module according to the aforementioned second embodiment.

Although the present invention has been described and illustrated in detail, it is clearly understood that the same is by way of illustration and example only and is not to be taken by way of limitation, the spirit and scope of the present invention being limited only by the terms of the appended claims.

For example, the stress relief regions formed on the power generating layer are formed in a groove shape in each of the aforementioned first to fourth embodiments, the present invention is not restricted to this but the stress relief regions may be formed in any shape so far as the power generating layer can be formed so as to include portions having a small thickness. For example, the stress relief region may alternatively formed in a hole shape.

While the present invention has been applied to the tandem solar cell module having the power generating layer constituted by the two layers of the photoelectric conversion layer made of the amorphous silicon layer and the photoelectric conversion layer made of the microcrystalline silicon layer in each of the aforementioned first to fourth embodiments, the present invention is not restricted to this but the present invention is also applicable to a solar cell module having a multiplayer structure in which the power generating layer includes three or more layer.

While the number, width, length, depth, etc. of the stress relief grooves (stress relief grooves 5f, 5g, 5h, 20e, 30e, 40e, etc.) shown in each of the aforementioned first to fourth embodiments may be properly selected such that the stress of the photoelectric conversion layer can be sufficiently relaxed and removed areas are reduced.

While EVA is employed as the sealing resin in each of the aforementioned first to fourth embodiments, the present invention is not restricted to this but ethylene series such as EEA, PVB, silicon, urethane, epoxy acrylate or the like may be alternatively employed.

While PET is employed as the back sheet in each of the aforementioned first to fourth embodiments, the present invention is not restricted to this but a simple substance such as fluororesin (ETFE, PVDF, PCTFE, etc.), PC and glass, or structure in which a metal foil is held between the substances and metal (steel plate) such as SUS or galvalume may be alternatively employed.

The present invention is not restricted to the conditions of generating films of the respective layers and the conditions of laser irradiation for patterning the respective layers and other conditions shown in the aforementioned first to fourth embodiments. These conditions may be properly selected so as to function as a solar cell.

While the respective layers partially removed and separated with lasers in each of the aforementioned first to fourth embodiments, the present invention is not restricted to this but the respective layers may be removed and separated by dry etching and wet etching employing with a photoresist mask and a hard mask or the like.

While the amorphous silicon carbide layer is employed as the p layer of the photoelectric conversion layer made of the amorphous silicon layer in each of the aforementioned first to fourth embodiments, the present invention is not restricted to this.

A structure in which a translucent and conductive layer is held between two photoelectric conversion layers may be employed in each of the aforementioned first to fourth embodiments.

What is claimed is:

1. A solar cell module comprising:
a first cell and a second cell adjacent to each other, each including a first electrode layer, a power generating layer constituted by a first photoelectric conversion layer made of an amorphous silicon layer formed on a surface of said first electrode layer and a second photoelectric conversion layer made of a microcrystalline silicon layer and a second electrode layer formed on a surface of said power generating layer stacked with each other, wherein
a first electrode layer of said first cell and a second electrode layer of said second cell are electrically connected to each other,
a stress relief region having a thickness smaller than the thickness of overall said power generating layer is formed on a prescribed region of said power generating layer, and
said stress relief region is formed in a groove shape so as to extend in a direction substantially perpendicular to a direction for connecting said first cell and said second cell in plan view.

2. The solar cell module according to claim 1, wherein
said stress relief region of said power generating layer is formed in the groove shape in plan view, and
said stress relief region is filled up with said second electrode layer.

3. The solar cell module according to claim 2, wherein
a plurality of said groove-shaped stress relief regions are formed.

4. The solar cell module according to claim 3, wherein
said plurality of groove-shaped stress relief regions are formed over a substantially whole area of said power generating layer in plan view.

5. The solar cell module according to claim 1, wherein
said stress relief region is formed at least in the vicinity of a region where said first cell and said second cell are separated from each other in plan view.

6. The solar cell module according to claim 1, wherein
said stress relief region is formed in the groove shape so as to extend in the direction substantially perpendicular to the direction for connecting said first cell and said second cell and in a direction substantially parallel to the direction for connecting said first cell and said second cell in the form of a lattice in plan view.

7. The solar cell module according to claim 1, wherein
said stress relief region of said power generating layer is formed in the groove shape,
said second electrode layer includes a first opening region provided on a region corresponding to said stress relief region, and
said groove-shaped stress relief region and said first opening region are filled up with a first insulating member.

8. The solar cell module according to claim 7, wherein
said first opening region is formed so as to extend in the direction substantially perpendicular to the direction for connecting said first cell and said second cell and not so as to completely divide said second electrode layer in plan view.

9. The solar cell module according to claim 1, wherein
said second photoelectric conversion layer made of said microcrystalline silicon layer is constituted by a p layer, an i layer and an n layer and formed on an upper surface of said first photoelectric conversion layer, and
said stress relief region of said power generating layer is formed in the groove shape such that said i layer of said second photoelectric conversion layer is partially left.

10. The solar cell module according to claim 9, wherein
said groove-shaped stress relief region is formed so as to extend up to a position lower than half the thickness of said i layer of said second photoelectric conversion layer.

11. The solar cell module according to claim 1, wherein
said second photoelectric conversion layer made of said microcrystalline silicon layer is constituted by a p layer, an i layer and an n layer and formed on an upper surface of said first photoelectric conversion layer, and
said stress relief region of said power generating layer is formed in the groove shape so as to pass through said p layer, said i layer and said n layer of said second photoelectric conversion layer.

12. The solar cell module according to claim 11, wherein
said stress relief region of said groove shape is formed so as to pass through said second photoelectric conversion layer to reach said first photoelectric conversion layer.

13. The solar cell module according to claim 11, wherein
a second insulating member covers an inner surface of said groove-shaped stress relief region passing through said p layer, said i layer and said n layer of said second photoelectric conversion layer.

14. The solar cell module according to claim 11, wherein
said stress relief region of said power generating layer is formed in the groove shape, and
said second electrode layer includes a second opening region provided on a region corresponding to said groove-shaped stress relief region.

15. The solar cell module according to claim 14, wherein
a third insulating member covers an upper surface of said second electrode layer and inner surfaces of said groove-shaped stress relief region and said second opening region.

16. The solar cell module according to claim 15, wherein
said third insulating member has a waterproof function.
